(19) United States
(12) Patent Application Publication
(10) Pub. No.: US 2025/0189606 A1
(43) Pub. Date: Jun. 12, 2025

(54) Magnetic Field Measurement Device

(71) Applicants: SUMIDA CORPORATION, Tokyo (JP); Kyoto University, Kyoto (JP)

(72) Inventors: Yoshiharu YOSHII, Miyagi (JP); Shingo HAMADA, Miyagi (JP); Akifumi SAKO, Miyagi (JP); Yuki TAKEMURA, Miyagi (JP); Norikazu MIZUOCHI, Kyoto (JP)

(21) Appl. No.: 19/046,878

(22) Filed: Feb. 6, 2025

Related U.S. Application Data
(63) Continuation of application No. PCT/JP2023/039837, filed on Nov. 6, 2023.

(30) Foreign Application Priority Data
Oct. 13, 2022 (JP) 2022-164955

(51) Int. Cl. G01R 33/26; G01R 33/00

(52) U.S. Cl. CPC G01R 33/26; G01R 33/0011

(57) ABSTRACT

A microwave from a high frequency magnetic field generator and a static magnetic field from a magnet are applied to a magnetic resonance member. An FT senses a measured magnetic field with a primary coil and applies an applied magnetic field corresponding to the sensed measured magnetic field to the magnetic resonance member with a secondary coil. A light guide member guides incident light of a specific wavelength to the magnetic resonance member, and a light guide member guides fluorescence generated by the magnetic resonance member from the magnetic resonance member. The magnetic resonance member is arranged to be sandwiched between an end surface of the light guide member and an end surface of the light guide member in a hollow part of the secondary coil of the FT and in a hollow part of the magnet. In addition, the secondary coil is a bobbinless coil.

### CROSS REFERENCE TO RELATED APPLICATIONS

This application is a continuation of PCT Application No. PCT/JP2023/039837, filed on Nov. 6, 2023, which claims priority to Japanese Patent Application No. 2022-164955, filed on Oct. 13, 2022. The contents of both of the above applications are expressly incorporated herein by reference in their entirety.

### BACKGROUND

### Technical Field

The present invention relates to a magnetic field measurement device.

### Related Art

A magnetic field measurement device performs magnetic measurement using optically detected magnetic resonance (ODMR) in which electron spin resonance of a sensing member such as a diamond structure having nitrogen and lattice defects (NV center: Nitrogen Vacancy Center) is utilized (for instance, refer to Japanese Patent Publication Number 2020-8298). In the ODMR, a static magnetic field is applied to a magnetic resonance member such as diamond that has the NV center in separation from a measured magnetic field, and at the same time, laser light (excitation light and measuring light) and a microwave are applied in a predetermined sequence. An amount of light of fluorescence emitted from the magnetic resonance member is detected and a magnetic flux density of the measured magnetic field is derived based on the amount of light.

For instance, in Ramsey pulse sequence, (a) excitation light is irradiated to an NV center, (b) a first n/2 pulse of a microwave is applied to the NV center, (c) a second n/2 pulse of the microwave is applied to the NV center at a predetermined time interval tt from the first n/2 pulse, (d) a light emission amount from the NV center is measured by irradiating the measuring light to the NV center, and (e) a magnetic flux density is derived based on the measured light emission amount. Further, in a spin echo pulse sequence, (a) the excitation light is irradiated to the NV center, (b) the first n/2 pulse of the microwave is applied to the NV center at a phase of 0 degrees of a measured magnetic field, (c) a n pulse of the microwave is applied to the NV center at a phase of 180 degrees of the measured magnetic field, (d) the second n/2 pulse of the microwaves is applied to the NV center at a phase of 360 degrees of the measured magnetic field, (e) the light emission amount from the NV center is measured by irradiating the measuring light to the NV center, and (f) the magnetic flux density is derived based on the measured light emission amount.

Further, a magnetic sensor has a superconducting quantum interference device (SQUID) and a magnetic flux transformer (flux transformer) that detects a measured magnetic field using a pickup coil and applies it to the SQUID using an input coil (for instance, refer to Japanese Patent Publication Number H08-75834).

The above-mentioned magnetic field measurement device applies laser light, a microwave, and a static magnetic field to the magnetic resonance member in addition to the measured magnetic field. Thus, means for respectively applying the laser light, the microwave, and the static magnetic field are mounted around the magnetic resonance member. Therefore, when the laser light, the microwave, and the static magnetic field are applied to the magnetic resonance member, in order to use a flux transformer, it is necessary to arrange a secondary coil of the flux transformer without interfering with the application of the laser light, the microwave, and the static magnetic field, and due to the geometric configuration, it is difficult to efficiently apply a magnetic field corresponding to the measured magnetic field to the magnetic resonance member by the flux transformer.

The present invention has an object that is to obtain a magnetic field measurement device in which a magnetic field corresponding to a measured magnetic field is efficiently applied to a magnetic resonance member by a flux transformer, and in which the magnetic resonance member, a high frequency magnetic field generator, and a magnet are easily arranged relative to a direction of a magnetic flux of a flux transformer, and as a result, making it easy to ensure a space for irradiating laser light.

### SUMMARY

A magnetic field measurement device according to the present invention includes a magnetic resonance member capable of quantum manipulation of electron spins (an electron spin quantum operation) using a microwave, a high frequency magnetic field generator that applies the microwave to the magnetic resonance member, a magnet that applies a static magnetic field to the magnetic resonance member, an irradiation device that irradiates incident light having a specific wavelength to the magnetic resonance member, a flux transformer that senses the measured magnetic field with a primary coil and applies an applied magnetic field corresponding to the sensed measured magnetic field to the magnetic resonance member with a secondary coil, a first light guide member in a cylindrical (columnar) shape that guides the incident light to the magnetic resonance member, and a second light guide member in a cylindrical (columnar) shape that guides fluorescence emitted by the magnetic resonance member from the magnetic resonance member. Further, the magnetic resonance member is arranged to be sandwiched between an end surface of the first light guide member and an end surface of the second light guide member in a hollow part of the secondary coil of the flux transformer and in a hollow part of the magnet. Further, the secondary coil is a bobbinless coil.

### Effects of the Invention

According to the present invention, it is possible to obtain a magnetic field measurement device in which a magnetic field corresponding to a measured magnetic field is efficiently applied to a magnetic resonance member by a flux transformer, and in which the magnetic resonance member, a high frequency magnetic field generator, and a magnet are easily arranged relative to a direction of a magnetic flux of the flux transformer, and as a result, making it easy to ensure a space for irradiating laser light.

### BRIEF DESCRIPTION OF THE DRAWINGS

FIG. 1 is a block diagram that shows a configuration of a magnetic field measurement device according to an embodiment of the present invention.

FIG. 2 is a cross-sectional view that shows a primary coil of a transformer shown in FIG. 1.

FIG. 3 is a diagram that explains the arrangement of the primary coil of the transformer when measuring a magnetic field.

FIG. 4 is a perspective view that shows a configuration example of a magnetic sensor part (a part) shown in FIG. 1.

FIG. 5 is a side view that shows a configuration example of an optical system in the magnetic sensor part shown in FIG. 1.

FIG. 6 is a perspective view (⅓) that shows a variation of the magnetic sensor part (a part) shown in FIG. 1.

FIG. 7 is a perspective view (⅔) that shows a variation of the magnetic sensor part (a part) shown in FIG. 1.

FIG. 8 is a perspective view (3/3) that shows a variation of the magnetic sensor part (a part) shown in FIG. 1.

FIG. 9 is a cross-sectional view that shows an example of a light guide member and a magnetic resonance member in a magnetic field measurement device according to a second embodiment.

FIG. 10 is a perspective view (⅓) that shows an example of a high frequency magnetic field generator according to a third embodiment.

FIG. 11 is a perspective view (⅔) that shows an example of the high frequency magnetic field generator according to the third embodiment.

FIG. 12 is a perspective view (3/3) that shows an example of the high frequency magnetic field generator according to the third embodiment.

FIG. 13 is a perspective view (½) that shows examples of a light guide member, a magnetic resonance member, and a secondary coil of a flux transformer in a magnetic field measurement device according to a fourth embodiment.

FIG. 14 is a perspective view (2/2) that shows examples of the light guide member, the magnetic resonance member, and the secondary coil of the flux transformer in the magnetic field measurement device according to the fourth embodiment.

FIG. 15 is a perspective view that shows a configuration of a magnetic sensor part (a part) in a magnetic field measurement device according to a fifth embodiment.

FIG. 16 is a perspective view (½) that shows an example of a secondary coil of a flux transformer according to a sixth embodiment.

FIG. 17 is a perspective view (2/2) that shows an example of the secondary coil of the flux transformer according to the sixth embodiment.

FIG. 18 is a perspective view that shows a configuration of a magnetic sensor part (a part) in a magnetic field measurement device according to a seventh embodiment.

FIG. 19 is a perspective view (½) that shows a configuration of a magnetic sensor part (a part) in a magnetic field measurement device according to an eighth embodiment.

FIG. 20 is a perspective view (2/2) that shows the configuration of the magnetic sensor part (a part) in the magnetic field measurement device according to the eighth embodiment.

FIG. 21 is a perspective view that shows a configuration of a magnetic sensor part (a part) in a magnetic field measurement device according to a ninth embodiment.

FIG. 22 is a cross-sectional view that shows the configuration of the magnetic sensor part (a part) in the magnetic field measurement device according to the ninth embodiment.

FIG. 23 is a perspective view that shows a configuration of a magnetic sensor part (a part) in a magnetic field measurement device according to a tenth embodiment.

FIG. 24 is a cross-sectional view that shows the configuration of the magnetic sensor part (a part) in the magnetic field measurement device according to the tenth embodiment.

### DETAILED DESCRIPTION

Embodiments of the present invention will be explained below with reference to the drawings.

### First Embodiment

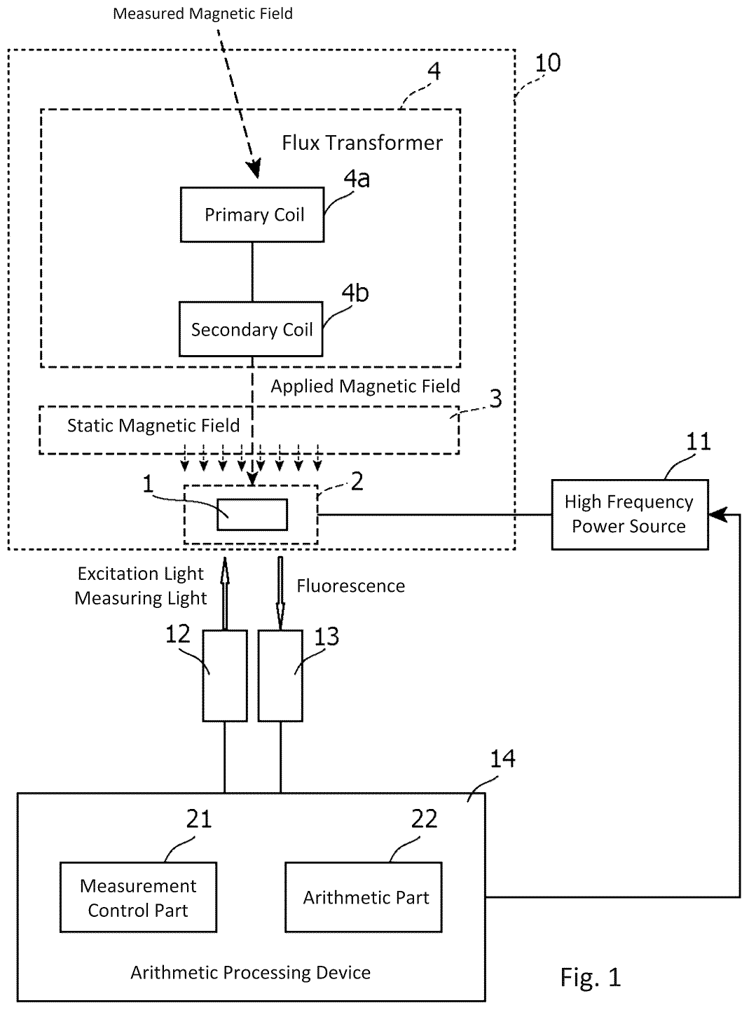

FIG. 1 is a block diagram that shows a configuration of a magnetic field measurement device according to an embodiment of the present invention. The magnetic field measurement device shown in FIG. 1 has a magnetic sensor part 10, a high frequency power source 11, an irradiation device 12, a light receiving device 13, and an arithmetic processing device 14.

The magnetic sensor part 10 detects a magnetic field to be measured (a measured magnetic field) (for instance, such as an intensity and a direction of the magnetic field) at a predetermined position (for instance, on or above a surface of an object to be inspected). Further, the measured magnetic field may be an alternating magnetic field with a single frequency or an alternating magnetic field with a predetermined cycle having a plurality of frequency components.

In this embodiment, the magnetic sensor part 10 has a magnetic resonance member 1, a high frequency magnetic field generator 2, a magnet 3, and a flux transformer 4.

The magnetic resonance member 1 has a crystal structure and is a member in which it is capable of an electron spin quantum operation by a microwave at a frequency that corresponds to arrangement directions of defects and impurities in a crystal lattice (based on Rabi oscillation).

In this embodiment, the magnetic resonance member 1 is an optically detected magnetic resonance member having a plurality (that is, an ensemble) of specific color centers. This specific color center has an energy level capable of Zeeman splitting, and at the same time, can take a plurality of directions in which shift widths of the energy level at the time of Zeeman splitting are different from each other.

Here, the magnetic resonance member 1 is a member such as a diamond that includes a plurality of NV (Nitrogen Vacancy) centers as a specific color center of a single category (or type). In the case of the NV center, a ground state is a triplet state of ms=0, +1, −1 and a level of ms=+1 and a level of ms=−1 undergo Zeeman splitting. Note that the color center included in the magnetic resonance member 1 may be a color center other than the NV center.

The high frequency magnetic field generator 2 applies the above-mentioned microwave to the magnetic resonance member 1.

Further, the magnet 3 applies a static magnetic field (a direct current (DC) magnetic field) to the magnetic resonance member 1. Here, the magnet 3 is a ring-type permanent magnet, such as a ferrite magnet, an alnico magnet, or a samarium cobalt magnet.

The magnetic resonance member 1 is provided with the plurality of color centers (here, the NV centers) in which it is capable of the electron spin quantum operation by the above-mentioned microwaves. The magnet 3 applies the substantially uniform static magnetic field to a predetermined region (an irradiation region of excitation light and measuring light) of the magnetic resonance member 1 and makes the energy levels of the plurality of specific color centers (here, the plurality of NV centers) within the magnetic resonance member 1 undergo Zeeman splitting. For instance, the static magnetic field is applied as a difference or a ratio between the maximum value and the minimum value of the intensities of the static magnetic field in the predetermined region is equal to or less than a predetermined value.

In the case of the NV center, since the color center is formed by a defect (vacancy) (V) and nitrogen (N) as an impurity in the diamond crystal, there are four possible positions for adjacent nitrogen (N) with respect to the defect (vacancy) (V) in the diamond crystal (that is, the arrangement directions of a pair of the vacancy and the nitrogen). Sub-levels (that is, the energy level from the ground) after Zeeman splitting respectively corresponding to these arrangement directions are different from each other. Therefore, in a characteristic of a fluorescence intensity after Zeeman splitting due to a static magnetic field with respect to a frequency of the microwave, in correspond with each direction i (i=1, 2, 3, 4), four pairs of dip frequencies (fit, fi−) that are different from one another appear. Here, the above-mentioned frequency of the microwave (wavelength) is set in correspond with any of the dip frequencies of these four pairs of dip frequencies.

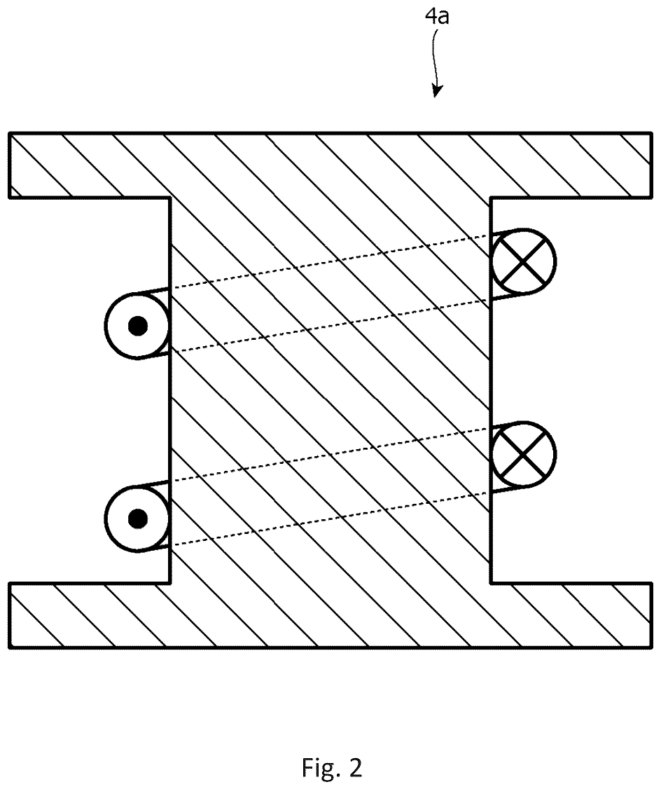

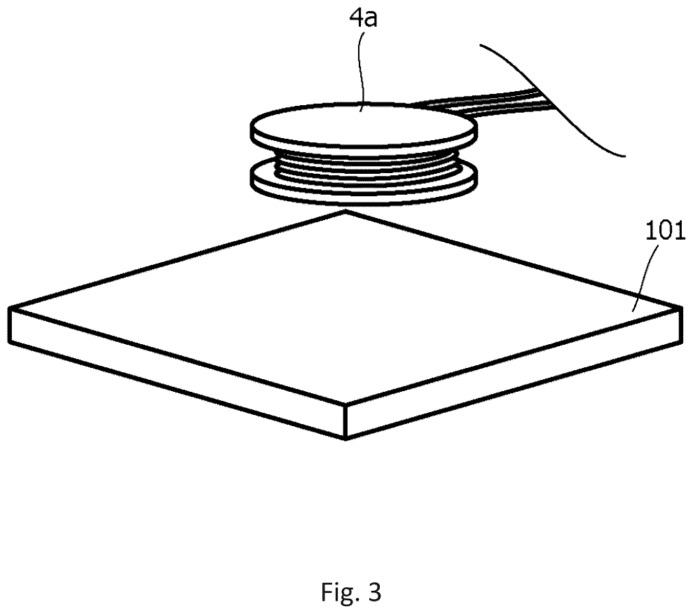

Further, the flux transformer 4 has a primary coil 4a and a secondary coil 4b that is electrically connected to the primary coil 4a via a cable and so on (such as a coaxial cable or a litz wire). As shown in FIG. 2, the primary coil 4a is composed of a winding having 0.5 to several tens of turns. Furthermore, as shown in FIG. 3, for instance, the primary coil 4a senses the measured magnetic field at a predetermined measurement position above an object to be measured 101 (a measured object 101), and the secondary coil 4b applies an applied magnetic field (a magnetic field being transmitted from the measurement position by the flux transformer 4) corresponding to the measured magnetic field being sensed at the measurement position to the magnetic resonance member 1. That is, the primary coil 4a induces an electrical signal corresponding to the sensed measured magnetic field, and the secondary coil 4b induces an applied magnetic field corresponding to the electrical signal.

Furthermore, an irradiation device 12 and a light receiving device 13 are provided as a detection device for detecting the fluorescence that is generated from the magnetic resonance member 1 by a physical phenomenon corresponding to the above-mentioned applied magnetic field.

The irradiation device 12 generates laser light (here, the excitation light of a predetermined wavelength and the measuring light of a predetermined wavelength for the ODMR) to be irradiated to the magnetic resonance member 1 and irradiates the laser light to the magnetic resonance member 1 as an optically detected magnetic resonance member via an optical system explained below.

Furthermore, when the measuring light is irradiated, the light receiving device 13 receives and detects the fluorescence that is emitted from the magnetic resonance member 1 via the optical system explained below.

The arithmetic processing device 14 has, for instance, a computer, executes a program by the computer, and operates as various processing units. In this embodiment, the arithmetic processing device 14 stores detected optical or electrical signal data in a storage device (such as a memory) that is not shown and performs control and calculation operations as a a measurement control part 21 and an arithmetic part 22.

The measurement control part 21 controls the high frequency power source 11 and specifies a detection value of the above-mentioned physical phenomenon (here, the fluorescence intensity) that is detected by the above-mentioned detection device (here, the irradiation device 12 and the light receiving device 13).

In this embodiment, the measurement control part 21 controls the high frequency power source 11 and the irradiation device 12 according to a predetermined measurement sequence based on, for instance, the ODMR, and specifies a detected light amount of the fluorescence being detected by the light receiving device 13. For instance, the irradiation device 12 has such as a laser diode as a light source, the light receiving device 13 has such as a photodiode as a light receiving element, and the measurement control part 21 specifies the above-mentioned detected light amount based on an output signal of the light receiving device 13 that is obtained by amplifying an output signal of the light receiving element.

The arithmetic part 22 calculates the measured magnetic field (an intensity, a waveform, and so on) at the above-mentioned measurement position based on the detection value that is obtained by the measurement control part 21 and stored in the storage device.

Further, the above-mentioned measurement sequence is set according to such as a frequency of the measured magnetic field. For instance, when the measured magnetic field is an alternating magnetic field with a relatively high frequency, a spin echo pulse sequence (such as a Hahn echo sequence) is applied as this measurement sequence. However, the measurement sequence is not limited to the above configuration. Furthermore, for instance, when the measured magnetic field is an alternating magnetic field with a relatively low frequency, a magnetic field can be measured several times in one period (cycle) of the measured magnetic field by using a Ramsey pulse sequence (that is, a measurement sequence for a direct current (DC) magnetic field) so that the measured magnetic field (an intensity, a waveform, and so on) may be specified based on the results of these magnetic field measurement.

The magnetic sensor part 10 will be explained in detail below.

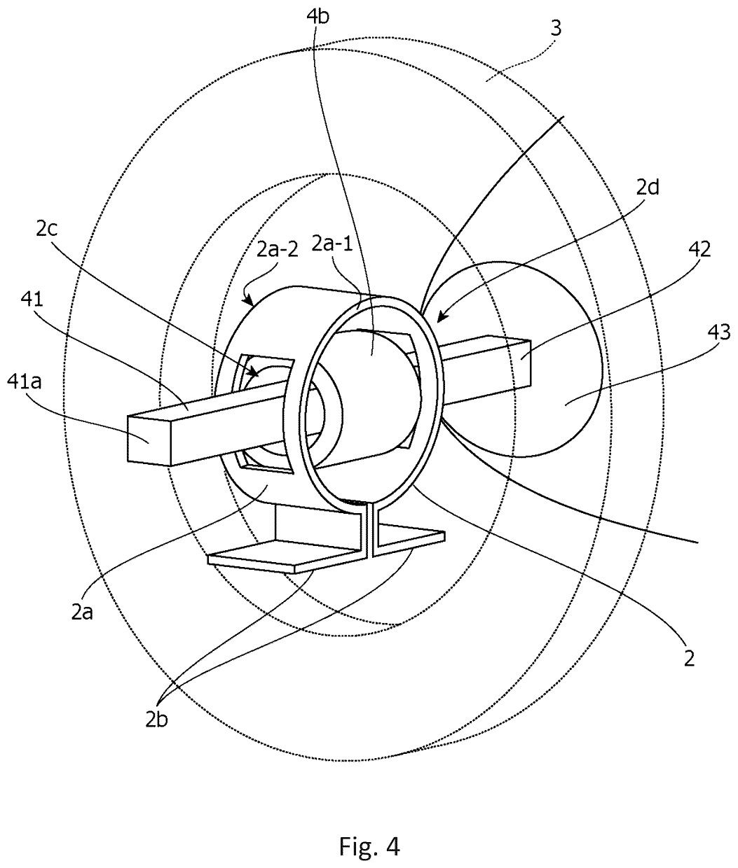

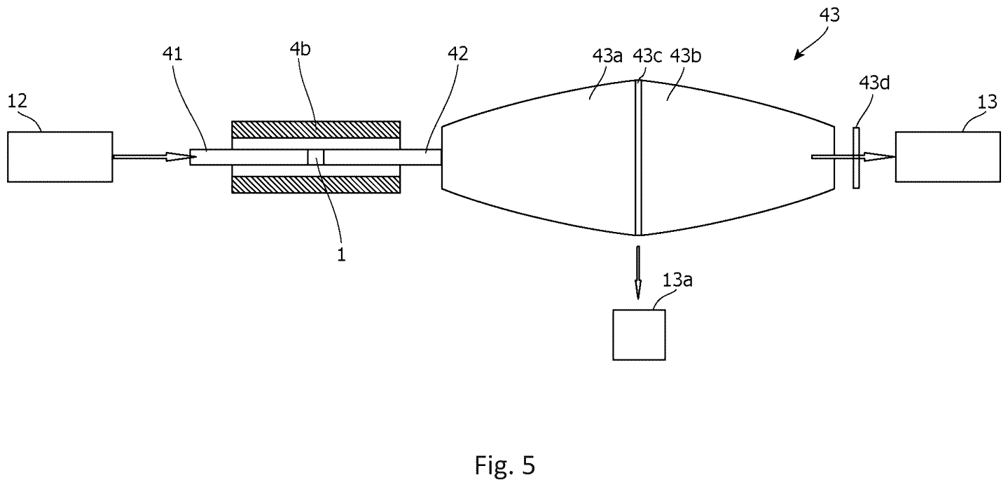

FIG. 4 is a perspective view that shows a configuration example of the magnetic sensor part 10 (a part) shown in FIG. 1. FIG. 5 is a side view that shows a configuration example of an optical system in the magnetic sensor part 10 shown in FIG. 1.

In this embodiment, for instance, as shown in FIGS. 4 and 5, the high frequency magnetic field generator 2 is a plate-shaped coil and has a substantially circular coil part 2a that emits the microwave into its hollow part and terminal parts 2b that extend from both ends of the coil part 2a and are fixed to such as a substrate that is not shown. The high frequency power source 11 generates a high frequency current of the microwave and is conductively connected to the high frequency magnetic field generator 2. The coil part 2a of the high frequency magnetic field generator 2 conducts two currents that are mutually in parallel at a predetermined interval so as to sandwich the magnetic resonance member 1 at both end surface parts 2a-1 and 2a-2 of the coil part and emit the above-mentioned microwave. Here, the high frequency magnetic field generator 2 is the plate-shaped coil, however, because the current O 41 the microwave flows through the end surface parts 2a-1 and 2a-2 of the coil part 2a due to a skin effect, two currents are formed. As a result, the microwave with a spatially substantially uniform intensity is applied to the magnetic resonance member 1.

Further, as shown in FIGS. 4 and 5, the magnetic sensor part 10 further has light guide members 41 and 42.

The light guide member 41 is a columnar (here, rectangular columnar) member that transmits light, and guides the incident light from the irradiation device 12 to the magnetic resonance member 1. The light guide member 42 is a columnar (here, rectangular columnar) member that transmits light, and guides the fluorescence emitted by the magnetic resonance member 1 from the magnetic resonance member 1 toward the light receiving device 13. The light guide members 41 and 42 are members, for instance, made of glass, and have cross sections of the same shape in a direction perpendicular to a longitudinal direction.

Further, the magnetic resonance member 1 is arranged to be sandwiched between an end surface of the light guide member 41 and an end surface of the light guide member 42 in a hollow part of the secondary coil 4b of the flux transformer 4 and in a hollow part of the magnet 3.

Specifically, the magnetic resonance member 1 is plate-shaped in, for instance, a substantially rectangular parallelepiped shape. One of two opposing surfaces of the magnetic resonance member 1 is in surface contact with or surface-joined (for instance, with an adhesive) to the end surface of the light guide member 41, and the other of two opposing surfaces is in surface contact with or surface-joined (for instance, with an adhesive) to the end surface of the light guide member 42. As a result, the light guide members 41 and 42, and the magnetic resonance member 1 are arranged on a straight line.

The secondary coil 4b is a bobbinless coil and is fixed by a support member that is not shown that supports an outer periphery of the secondary coil 4b or by a filling member explained below so that a central axis of the secondary coil 4b is arranged to substantially align (coincide) with centers of the light guide members 41 and 42, and the magnetic resonance member 1, and at the same time, is arranged to be substantially perpendicular to a central axis of the coil part 2a of the high frequency magnetic field generator 2. The secondary coil 4b is wound in a ring shape (here, in a circular annular shape) with a predetermined turn ratio to the primary coil 4a. Further, for instance, as shown in FIGS. 4 and 5, the secondary coil 4b is arranged in the hollow part of the substantially circular and plate-shaped coil part 2a in the high frequency magnetic field generator 2. When the secondary coil 4b is made of a thin wire with a large number of turns, in order to prevent a coil conducting wire from fraying, for instance, a self-fusing wire may be used for the coil conducting wire, or the coil conducting wire may be wound around a bobbin jig and coated with such as adhesive, and thereafter, the bobbin jig may be removed. As a result, the bobbinless secondary coil 4b is formed.

Further, openings 2c and 2d are formed on the side surfaces of the substantially circular and plate-shaped coil part 2a in the high frequency magnetic field generator 2. The openings 2c and 2d are located in an axial direction of the secondary coil 4b when viewed from the secondary coil 4b. Further, the openings 2c and 2d are arranged at positions opposite to each other via the center of the coil part 2a in a direction substantially perpendicular to the central axis direction of the coil part 2a.

As a result, a direction of the microwave (the magnetic field) that is generated by the high frequency magnetic field generator 2 becomes substantially perpendicular to a direction of the magnetic field that is generated by the secondary coil 4b. Further, it is preferred that an angle between the direction of the microwave (the magnetic field) from the high frequency magnetic field generator 2 and the direction of the magnetic field from the secondary coil 4b is in a range of 90 degrees+8 degrees. Further, it is most preferred that the angle is 90 degrees.

Further, sizes of the openings 2c and 2d are determined by a size of the above-mentioned irradiation region in the magnetic resonance member 1 and a size of a region in the coil part 2a through which a current flows due to a skin effect. In this embodiment, since the irradiation region in the magnetic resonance member 1 is rectangular or circular and the plate-shaped coil of the high frequency magnetic field generator 2 is substantially circular, the openings 2c and 2d are arc-shaped rectangles. Further, the area of a projection region of the openings 2c and 2d onto the magnetic resonance member 1 is larger than the area of the irradiation region. Thus, the openings 2c and 2d are designed so that the projection region includes the irradiation region.

Furthermore, the plate-shaped magnetic resonance member 1 and the columnar light guide members 41 and 42 are arranged and fixed in the openings 2c and 2d. That is, in the first embodiment, the high frequency magnetic field generator 2 has the substantially circular and plate-shaped coil part 2a that emits the microwave. The coil part 2a has two openings 2c and 2d. The first light guide member 41 is arranged so as to penetrate one of the two openings 2c and 2d (the opening 2c). Further, the second light guide member 42 is arranged so as to penetrate the other of the two openings 2c and 2d (the opening 2d).

In addition, in this embodiment, as shown in FIG. 4, the magnet 3 is the ring-type magnet. The secondary coil 4b is wound in a ring shape. A central axis of the magnet 3 and a central axis of the secondary coil 4b are aligned (coincident) with each other. The magnetic resonance member 1, the light guide member 41, and the light guide member 42 are arranged on the central axis.

For instance, as shown in FIG. 4, the above-mentioned magnetic resonance member 1 is arranged at a position that is in the hollow part of the secondary coil 4b of the flux transformer 4 and that is in the hollow part of the magnet 3. Further, in this embodiment, the secondary coil 4b is arranged in the hollow part of the magnet 3. The magnetic resonance member 1 is arranged within a central area having a radius from a center point, where the radius (from the center point) is equal to (a radius of a cross section×a %), in the cross section that is perpendicular to each of the central axis of the magnet 3 and the central axis of the secondary coil 4b. It is specifically preferred that the magnetic resonance member 1 is arranged at the central point. Here, “a” is equal to or less than 30. It is more preferred that “a” is equal to or less than 20. It is even more preferred that “a” is equal to or less than 10. Further, it is even more preferred that “a” is equal to or less than 5.

Therefore, in this embodiment, because an application direction of above-mentioned applied magnetic field by the secondary coil 4b is the same as an application direction of the above-mentioned static magnetic field by the magnet 3, a change of the fluorescence intensity at the above-mentioned dip frequency is enhanced and the sensitivity is increased by applying the above-mentioned static magnetic field.

Further, in the magnetic resonance member 1, as the arrangement direction(s) of the above-mentioned defect(s) and impurity (ies) is (are) substantially aligned (coincident) with the above-mentioned direction of the static magnetic field (and the direction of the applied magnetic field), a crystal of the magnetic resonance member 1 is formed and the direction of the magnetic resonance member 1 is set.

Further, it is preferred that the angle (absolute value) between the arrangement direction of the above-mentioned defect and impurity and the above-mentioned direction of the static magnetic field (and the direction of the applied magnetic field) is equal to or less than 8 degrees. Further, it is most preferred that the angle is 0 degrees. In addition, it is preferred that the angle (absolute value) between the above-mentioned direction of the static magnetic field and the above-mentioned direction of the applied magnetic field is equal to or less than 8 degrees. Further, it is most preferred that the angle is 0 degrees.

Furthermore, in the direction of the central axis of the magnet 3, the magnetic resonance member 1 is arranged at a central section of a width of the ring-type magnet 3. The “central section” here refers to a space from the center point of the central axis of the ring-type magnet 3 to + (“½×b %” of a length of the central axis) along the direction of the central axis. Here, “b” is equal to or less than 30. It is more preferred that “b” is equal to or less than 20. It is even more preferred that “b” is equal to or less than 10. Further, it is even more preferred that “b” is equal to or less than 5.

In addition, in this embodiment, the magnetic resonance member 1 is arranged at the center of the width of the ring-type magnet 3 (in other words, the magnetic resonance member 1 is arranged at a position substantially equidistant from both end surfaces of the magnet 3). Furthermore, in the direction of the central axis of the secondary coil 4b of the transformer 4, the magnetic resonance member 1 is arranged at a central section of a width of the secondary coil 4b. The “central section” here refers to a space from the center point of the central axis of secondary coil 4b to + (“½×c %” of a length of the central axis) along the central axis direction. Here, “c” is equal to or less than 30. It is more preferred that “c” is equal to or less than 20. It is even more preferred that “c” is equal to or less than 10. Further, it is even more preferred that “c” is equal to or less than 5. In this embodiment, the magnetic resonance member 1 is arranged at the center of the width of the secondary coil 4b (in other words, the magnetic resonance member 1 is arranged at a position substantially equidistant from both end surfaces of the secondary coil 4b). Furthermore, on a plane perpendicular to the central axis of the hollow part of magnet 3, it is preferred that a cross-sectional area of the hollow part is 100 times or more larger than an area of the irradiation region of the excitation light and the measuring light in the magnetic resonance member 1. Specifically, in the cross section of the hollow part, it is preferred that a length of a diameter of the hollow part in a radial direction is 10 times or more longer than a diameter of the irradiation region of the measuring light. In this embodiment, for instance, the irradiation region of the measuring light is 50 μm×100 μm, and the cross-sectional area of the hollow part is equal to or more than 500 μm×1000 μm. As a result, a uniform static magnetic field (a static magnetic field having substantially constant direction and strength) is applied to the irradiation region of the excitation light and the measuring light.

Further, as shown in, for instance, FIG. 5, the fluorescence that is emitted by the magnetic resonance member 1 is concentrated from the magnetic resonance member 1 through the light guide member 42 and a predetermined optical system 43 toward the light receiving device 13. In this embodiment, as shown in, for instance, FIG. 5, the optical system 43 has compound parabolic concentrators (CPCs) 43a and 43b. Note that this optical system 43 may have a different lens configuration. An end surface of the light guide member 42 is in surface contact with or surface-joined (for instance, with an adhesive) to an end surface of the CPC 43a. The fluorescence that is guided by the light guide member 42 enters in an inside of the CPC 43a through this end surface.

This optical system 43 is configured to prevent the above-mentioned incident light (that is, the remaining component that has passed through the magnetic resonance member 1) from entering into the light receiving device 13. Specifically, as shown in, for instance, FIG. 5, the optical system 43 is provided with a dichroic mirror 43c that transmits the above-mentioned fluorescence and reflects the above-mentioned incident light, and/or a long pass filter 43d that transmits the above-mentioned fluorescence and attenuates the above-mentioned incident light. In addition, the above-mentioned incident light that is reflected by the dichroic mirror 43c is detected by a reference light receiving device 13a, and the arithmetic part 22 corrects a measurement value of the measured magnetic field based on an amount of incident light (for instance, the deviation from a predetermined reference light amount) that is detected by the reference light receiving device 13a.

In this embodiment, the irradiation device 12 irradiates the magnetic resonance member 1 with the above-mentioned incident light along the above-mentioned central axis via the light guide member 41. As a result, the incident light enters into an inside of the light guide member 41 from an end surface 41a of the light guide member 41, and advances toward the magnetic resonance member 1 while being reflected by the side surfaces of the light guide member 41. As a result, since the light guide member 41 ensures a space through which the optical path of the laser light (measuring light) from the irradiation device 12 and the optical path of the fluorescence from the magnetic resonance member 1 pass, the measuring light and the fluorescence are prevented from leaking into an external space.

In addition, a magnetic shield is provided around the magnetic resonance member 1 in the magnetic sensor part 10 so that an external magnetic field is not directly applied to the magnetic resonance member 1.

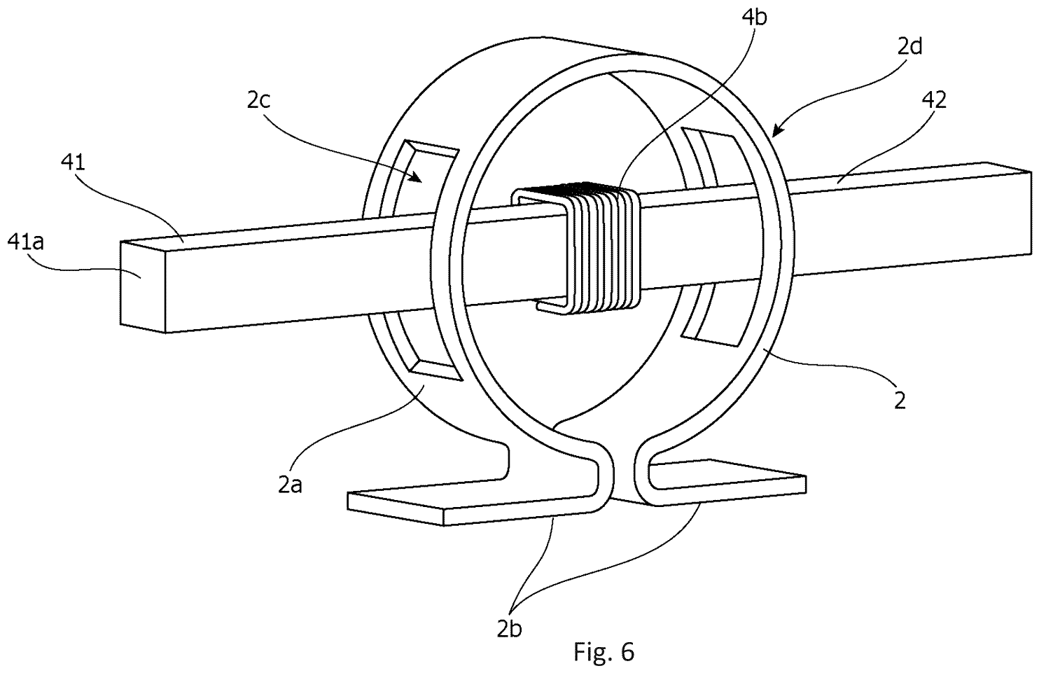

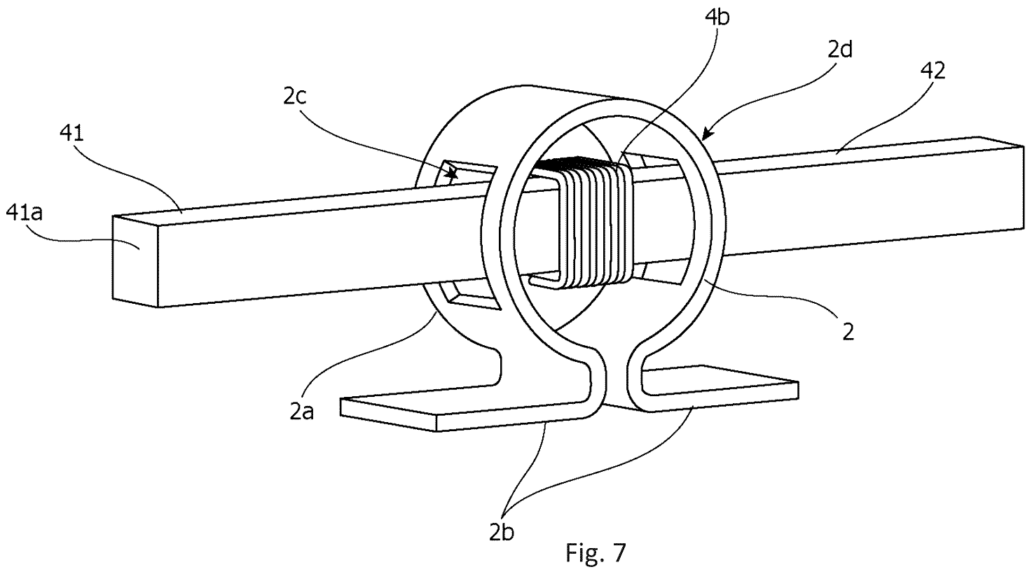

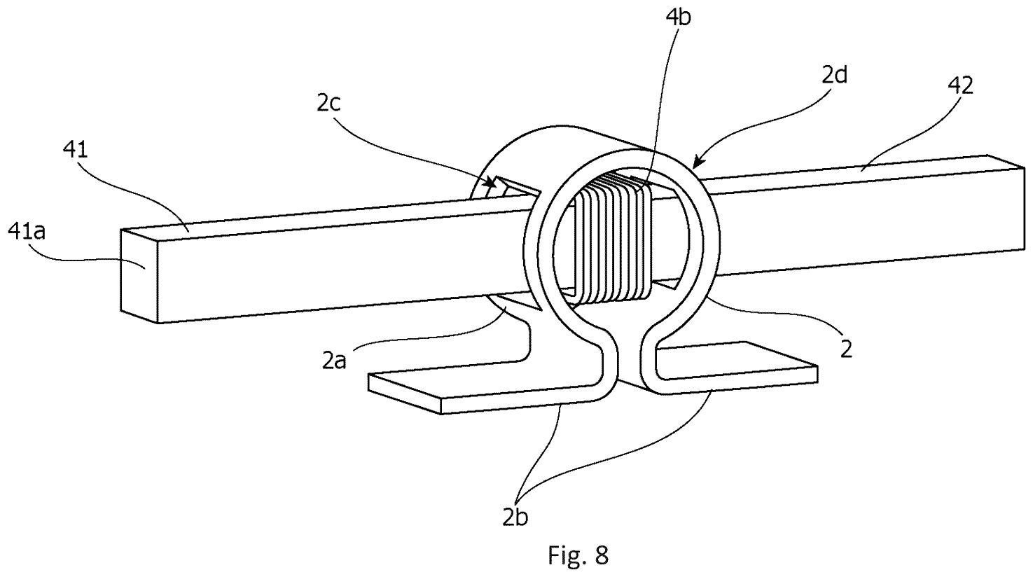

FIGS. 6-8 are perspective views that show variations of the magnetic sensor part 10 (a part) shown in FIG. 1. As shown in, for instance, FIGS. 6-8, the secondary coil 4b may be a ring-shaped coil that is wound in a rectangular shape corresponding to the shapes of the light guide members 41 and 42 and the magnetic resonance member 1. Furthermore, a diameter of the plate-shaped coil part 2a that is curved in a substantially annular shape is not particularly limited. The coil part 2a may have a size as shown in, for instance, FIGS. 6-8.

Next, an operation of the magnetic field measurement device according to the embodiment will be explained.

For instance, as shown in FIG. 3, the primary coil 4a of the flux transformer 4 in the magnetic sensor part 10 is arranged at a desired measurement position and in a desired direction with respect to the measured object 101. As a result, the measured magnetic field is sensed by the primary coil 4a, and the applied magnetic field is induced by the secondary coil 4b and is applied to the magnetic resonance member 1. Further, the substantially uniform static magnetic field is applied to the magnetic resonance member 1 by the magnet 3 in the magnetic sensor part 10.

The measurement control part 21 controls the high frequency power source 11 and the irradiation device 12 so as to, according to a predetermined measurement sequence, apply the microwave from the high frequency magnetic field generator 2 to the magnetic resonance member 1 and at the same time, apply the laser light (the excitation light and the measuring light) from the irradiation device 12 to the magnetic resonance member 1 via the light guide member 41. The light receiving device 13 receives the fluorescence that is emitted from the magnetic resonance member 1 in correspond with the excitation light and the measuring light via the light guide member 42 and the optical system 43, and outputs an electrical signal corresponding to the light amount of fluorescence (the fluorescence intensity). The measurement control part 21 acquires the electrical signal. The arithmetic part 22 performs calculations corresponding to the measurement sequence based on a detection value of the fluorescence intensity and specifies a magnetic field (for instance, an intensity or a direction) at the measurement position.

As a result, the magnetic field at the measurement position is measured by the magnetic sensor part 10 (i.e., the magnetic resonance member 1). Note that the magnetic sensor part 10 may be scanned along a predetermined scanning path pattern, and the above-mentioned magnetic field measurements may be performed at a plurality of measurement positions on the scanning path.

As mentioned above, according to the first embodiment, the high frequency magnetic field generator 2 applies the microwave to the magnetic resonance member 1 in which it is capable of the electron spin quantum operation by the above-mentioned microwave. The magnet 3 applies the static magnetic field to the magnetic resonance member 1. The irradiation device 12 irradiates the magnetic resonance member 1 with the incident light of a specific wavelength. The flux transformer 4 senses the measured magnetic field by the primary coil 4a and applies the applied magnetic field corresponding to the sensed measured magnetic field to the magnetic resonance member 1 by the secondary coil 4b. The columnar light guide member 41 guides the incident light to the magnetic resonance member 1. The columnar light guide member 42 guides the fluorescence that is emitted by the magnetic resonance member 1 from the magnetic resonance member 1. Further, the magnetic resonance member 1 is arranged to be sandwiched between the end surface of the light guide member 41 and the end surface of the light guide member 42 in the hollow part of the secondary coil 4b of the flux transformer 4 and in the hollow part of the above-mentioned magnet 3. In addition, the secondary coil 4b of the flux transformer 4 is a bobbinless coil.

As a result, it is possible to apply the magnetic field corresponding to the measured magnetic field to the magnetic resonance member 1 together with the static magnetic field without interfering with the optical paths of the above-mentioned excitation light and measuring light (and fluorescence). Therefore, the flux transformer 4 can efficiently apply the magnetic field corresponding to the measured magnetic field to the magnetic resonance member 1 so as to enable magnetic field measurement. Further, it becomes easier to relatively arrange the magnetic resonance member 1, the high frequency magnetic field generator 2, and the magnet 3, and the direction of the magnetic flux of the flux transformer 4. In addition, it becomes easier to ensure the space for irradiating the laser light.

Next, a method of manufacturing the magnetic field measurement device according to the embodiment will be explained.

First of all, the magnetic resonance member 1, the high frequency magnetic field generator 2, the magnet 3, and the flux transformer 4 are respectively prepared.

Next, the high frequency magnetic field generator 2 is attached to a circuit board that is not shown. Further, from the viewpoint of miniaturization, when a semiconductor substrate such as SiC is utilized, the high frequency magnetic field generator 2 is integrally mounted on the substrate.

Next, the high frequency magnetic field generator 2 is fixed by fixing the circuit board, and at the same time, the secondary coil 4b of the flux transformer 4 is arranged so that the opening ends of the secondary coil 4b respectively face the openings 2c and 2d of the high frequency magnetic field generator 2. Note that the magnetic resonance member 1 is assembled so that one of the arrangement directions of the defects faces the center of the openings 2c and 2d. As a result, the magnetic flux that is generated from the high frequency magnetic field generator 2 becomes perpendicular to at least one outer surface of the magnetic resonance member 1.

Further, the light guide member 41, the magnetic resonance member 1, and the light guide member 42 are inserted through the openings 2c and 2d and fixed. At this time, the magnetic resonance member 1 is arranged in the central area and the central section of the secondary coil 4b. In addition, the direction and the position of each part are adjusted so that the magnetic flux that is generated from the high frequency magnetic field generator 2 and the magnetic flux that is generated from the secondary coil 4b are perpendicular to each other.

Furthermore, the magnet 3 is attached to an outside of the high frequency magnetic field generator 2. In addition, the irradiation device 12, the optical system 43, and the light receiving device 13 are separately installed and fixed.

The above method of manufacturing allows the magnetic resonance member 1, the high frequency magnetic field generator 2, and the magnet 3, and the direction of the magnetic flux of the flux transformer 4 to be adjusted in stages, and as a result, it makes it easy to arrange them relative to one another and eliminates the need for complicated adjustments after assembly.

### Second Embodiment

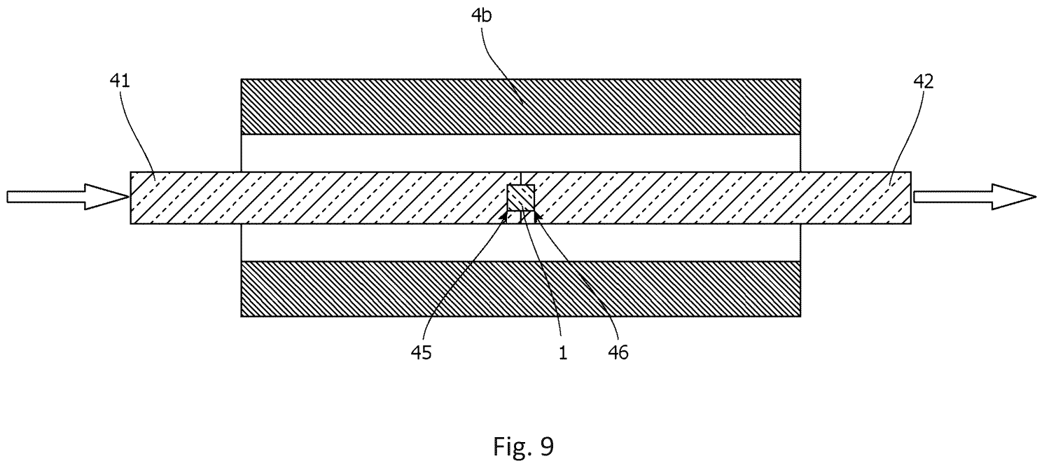

FIG. 9 is a cross-sectional view that shows an example of a light guide member and a magnetic resonance member in a magnetic field measurement device according to a second embodiment. In the second embodiment, either or both of the light guide members 41 and 42 (here, both) have recessed parts 45 and 46 corresponding to a shape of the magnetic resonance member 1 on the end surfaces. Further, the magnetic resonance member 1 is arranged in these recessed parts 45 and 46.

Specifically, the magnetic resonance member 1 is arranged in these recessed parts 45 and 46. Further, a portion of the end surface of the light guide member 41 other than the recessed part 45 and a portion of the end surface of the light guide member 42 other than the recessed part 46 are in surface contact or surface-joined (for instance, with an adhesive) with each other and fixed to each other.

Note that the other configurations and operations of the magnetic field measurement device according to the second embodiment are the same as those explained in any other embodiments. Therefore, the explanations of the other configurations and operations of the measurement device according to the second embodiment will be omitted.

### Third Embodiment

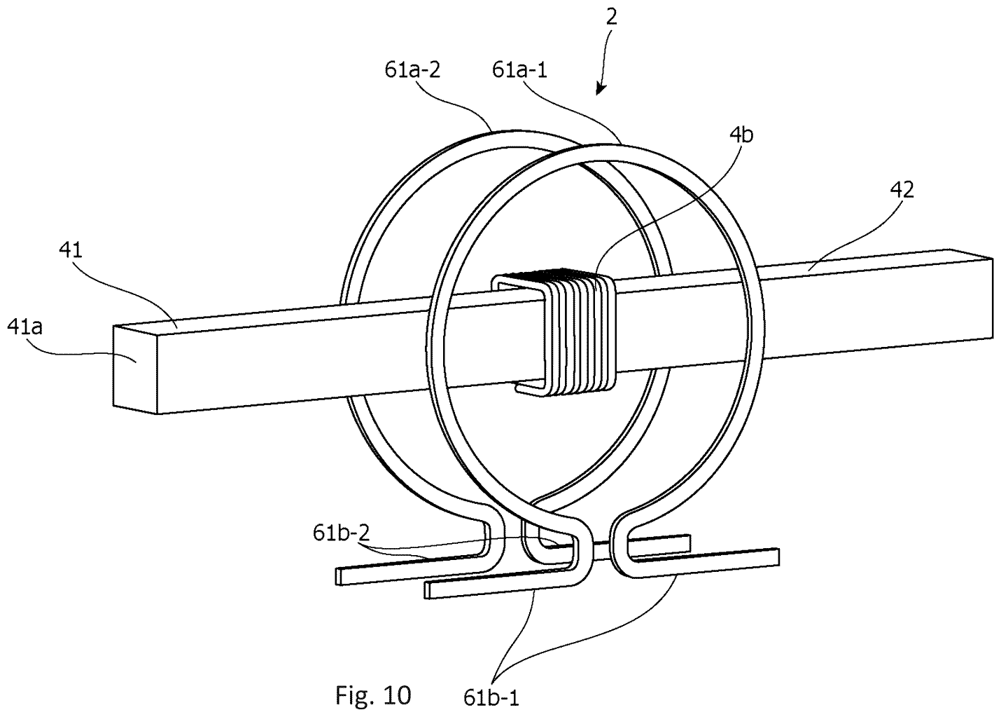

FIGS. 10-12 are perspective views that show examples of a high frequency magnetic field generator 2 according to a third embodiment. In the third embodiment, the high frequency magnetic field generator 2 has two coil parts 61a-1 and 61a-2 instead of the coil part 2a, and has terminal parts 61b-1 and 61b-2 instead of the terminal parts 2b.

For instance, as shown in FIG. 10, the high frequency magnetic field generator 2 has substantially circular coil parts 61a-1 and 61a-2 that respectively emit the microwave, and the terminal parts 61b-1 and 61b-2 that extend from both ends of the coil parts 61a-1 and 61a-2 and are fixed to such as a substrate that is not shown.

The coil parts 61a-1 and 61a-2 conduct two currents (currents having substantially the same amplitude and substantially the same frequency, and being synchronized with each other) that are parallel to each other at a predetermined interval so as to sandwich the magnetic resonance member 1, and emit the above-mentioned microwave. As a result, the microwave with a spatially substantially uniform intensity is applied to the magnetic resonance member 1.

In the first embodiment, the high frequency magnetic field generator 2 is a horizontally wound (×-winding) plate-shaped coil. However, in the third embodiment, the high frequency magnetic field generator 2 is a vertically wound (edgewise winding) plate-shaped coil.

Further, at least a part of the light guide member 41, at least a part of the light guide member 42, and the magnetic resonance member 1 are arranged in the space between the two coil parts 61a-1 and 61a-2.

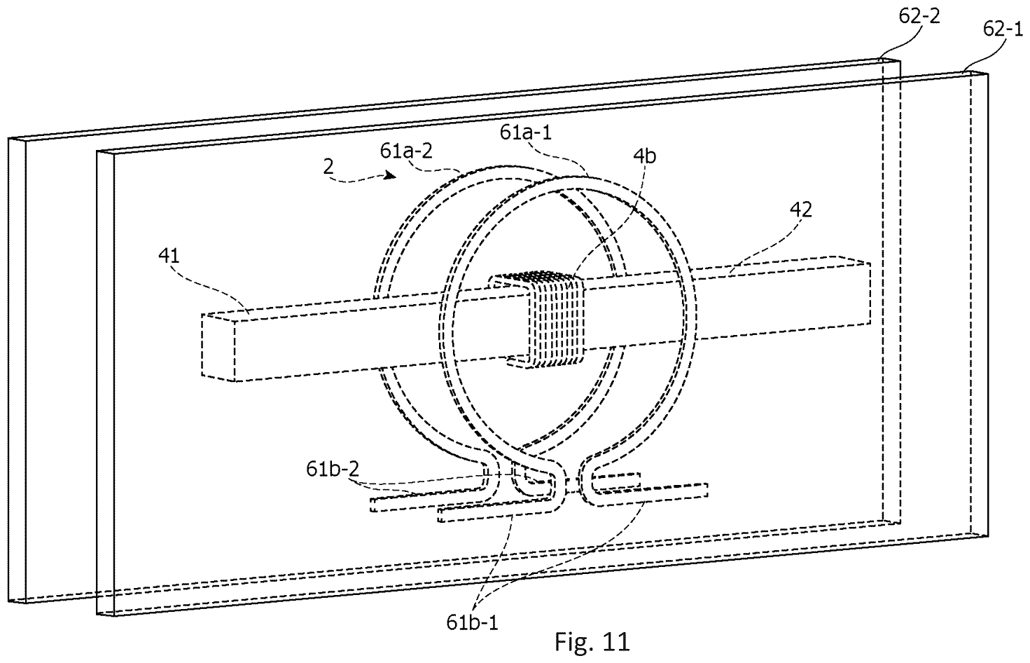

Furthermore, as shown in, for instance, FIG. 11, in the third embodiment, a plate member 62-1 and a plate member 62-2 that is arranged substantially in parallel to the plate member 62-1 are provided. The coil part 61a-1 is arranged on a surface of the plate member 62-1. The coil part 61a-2 is arranged on a surface of the plate member 62-2 facing the surface of the plate member 62-1.

Note that the plate members 62-1 and 62-2 may be substrates. The coil parts 61a-1 and 61a-2 may respectively be wiring patterns on these substrates. Moreover, the plate members 62-1 and 62-2 may be glass substrates or fluoropolymer (Polytetrafluoroethylene (PTEF)) substrates.

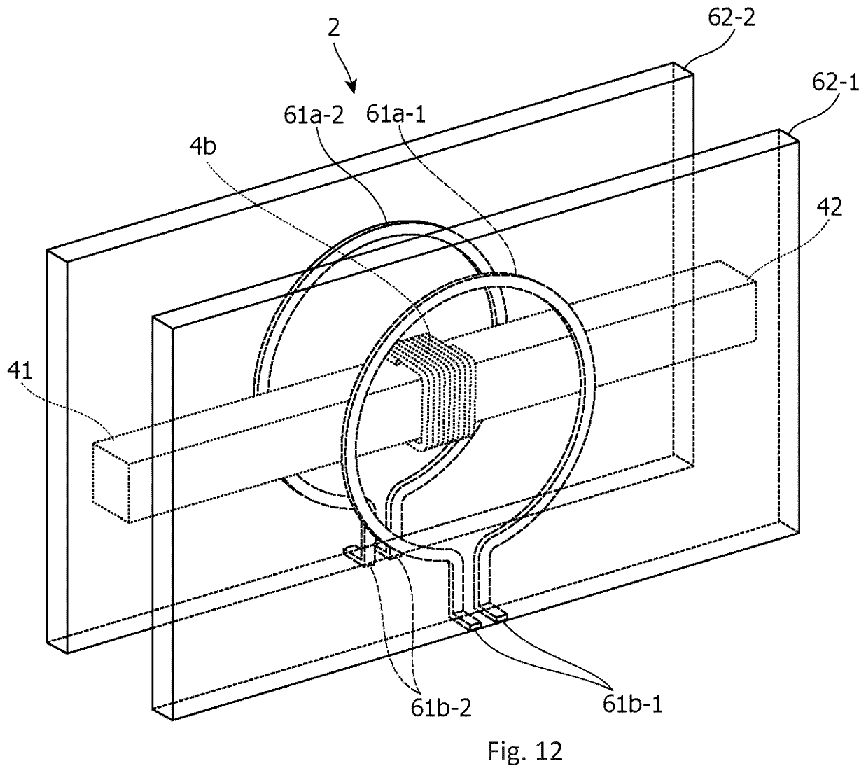

Furthermore, as shown in, for instance, FIG. 12, the terminal part 61b-1 may be bent at an edge of the plate member 62-1 and extend from the coil part 61a-1 along the side of the first plate member 62-1. The terminal part 61b-2 may be bent at an edge of the plate member 62-2 and extend from the coil part 61a-2 along the side of the plate member 62-2.

Note that the other configurations and operations of the magnetic field measurement device according to the third embodiment are the same as those explained in any other embodiments. Therefore, the explanations of the other configurations and operations of the measurement device according to the third embodiment will be omitted.

### Fourth Embodiment

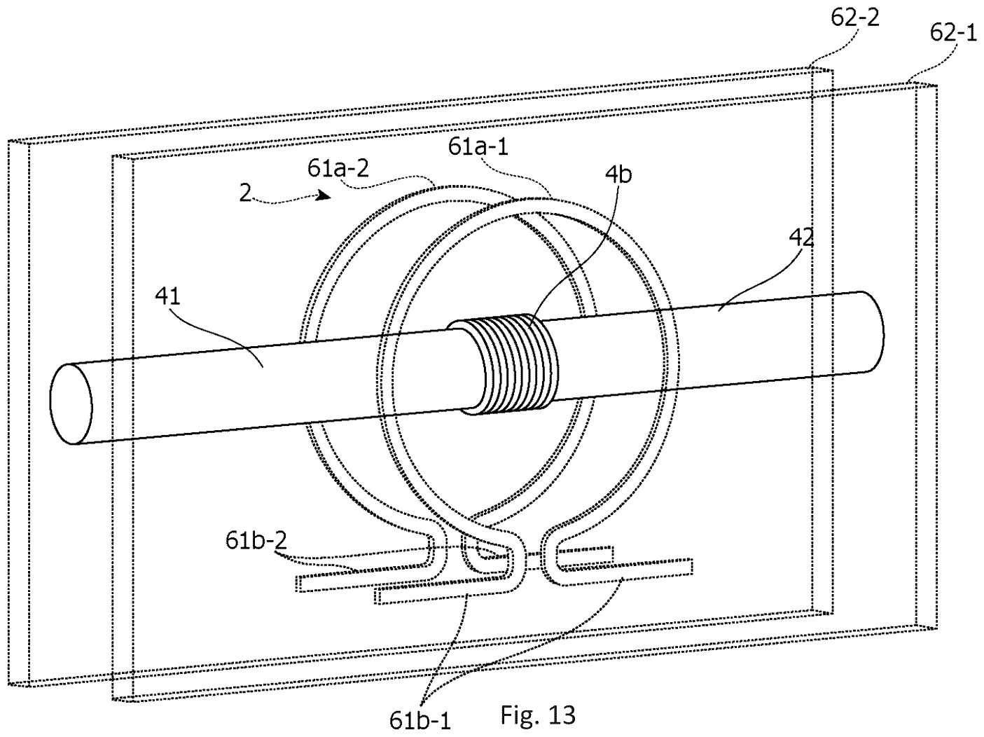

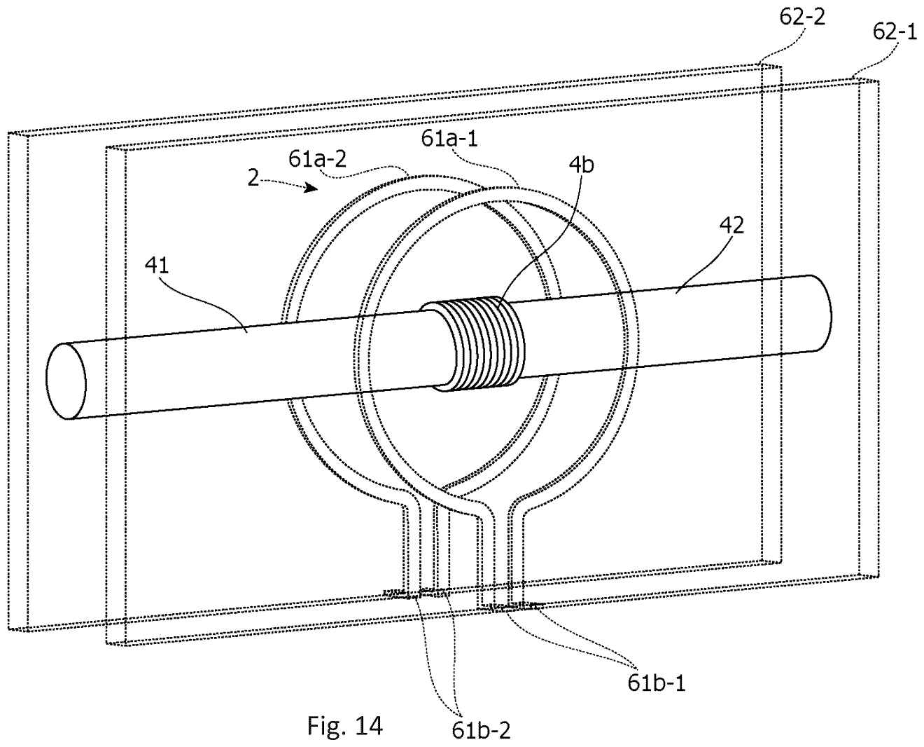

FIGS. 13 and 14 are perspective views that show examples of a light guide member, a magnetic resonance member, and a secondary coil of a flux transformer in a magnetic field measurement device according to a fourth embodiment. For instance, as shown in FIGS. 13 and 14, in the fourth embodiment, the light guide members 41 and 42 are in substantially cylindrical shapes. Other optical characteristics of the light guide members 41 and 42 in the fourth embodiment are the same as the optical characteristics of the light guide members 41 and 42 in the first embodiment. Here, FIG. 13 shows a modification of the light guide members 41 and 42 shown in FIG. 11. Further, FIG. 14 shows a modification of the light guide members 41 and 42 shown in FIG. 12.

Note that the magnetic resonance member 1 that is sandwiched between the light guide member 41 and the light guide member 42 may be in a substantially cylindrical shape (for instance, having the same diameter as the first light guide member 41). Further, recessed parts that are the same as those in the second embodiment may be provided. The magnetic resonance member 1 may be arranged in the recessed parts 45 and 46.

Note that the other configurations and operations of the magnetic field measurement device according to the fourth embodiment are the same as those explained in any other embodiments. Therefore, the explanations of the other configurations and operations of the measurement device according to the fourth embodiment will be omitted.

### Fifth Embodiment

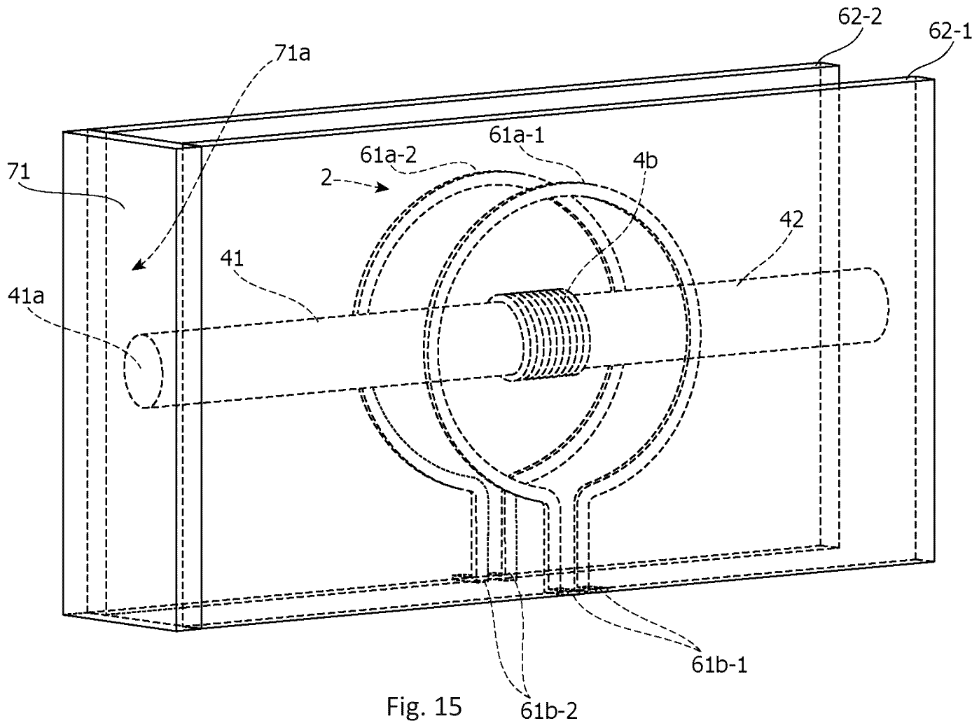

FIG. 15 is a perspective view that shows configuration of a magnetic sensor part (a part) in a magnetic field measurement device according to a fifth embodiment. For instance, as shown in FIG. 15, in the fifth embodiment, the magnetic sensor part 10 is provided with an optical member 71. The optical member 71 is arranged adjacent to the end surface 41a of the light guide member 41, transmits the above-mentioned excitation light, and reflects the fluorescence. Here, an end surface 71a of the optical member 71 is in contact with the end surface 41a of the light guide member 41.

For instance, in the optical member 71, a dielectric multilayer film is formed on the end surface 71a of a flat plate body made of such as transparent glass. This dielectric multilayer film transmits light having a wavelength (for instance, 533 nm) of the excitation light to the light guide member 41 and reflects light having a wavelength (for instance, 600 nm to 800 nm) of the fluorescence from the light guide member 41. As a result, the fluorescence advancing from the magnetic resonance member 1 to the light guide member 41 is reflected by the optical member 71, advances through the light guide members 41 and 42, and is received by the light receiving device 13. Therefore, the light amount of the fluorescence that is received by the light receiving device 13 is increased by the optical member 71.

Note that the other configurations and operations of the magnetic field measurement device according to the fifth embodiment are the same as those explained in any other embodiments. Therefore, the explanations of the other configurations and operations of the measurement device according to the fifth embodiment will be omitted.

### Sixth Embodiment

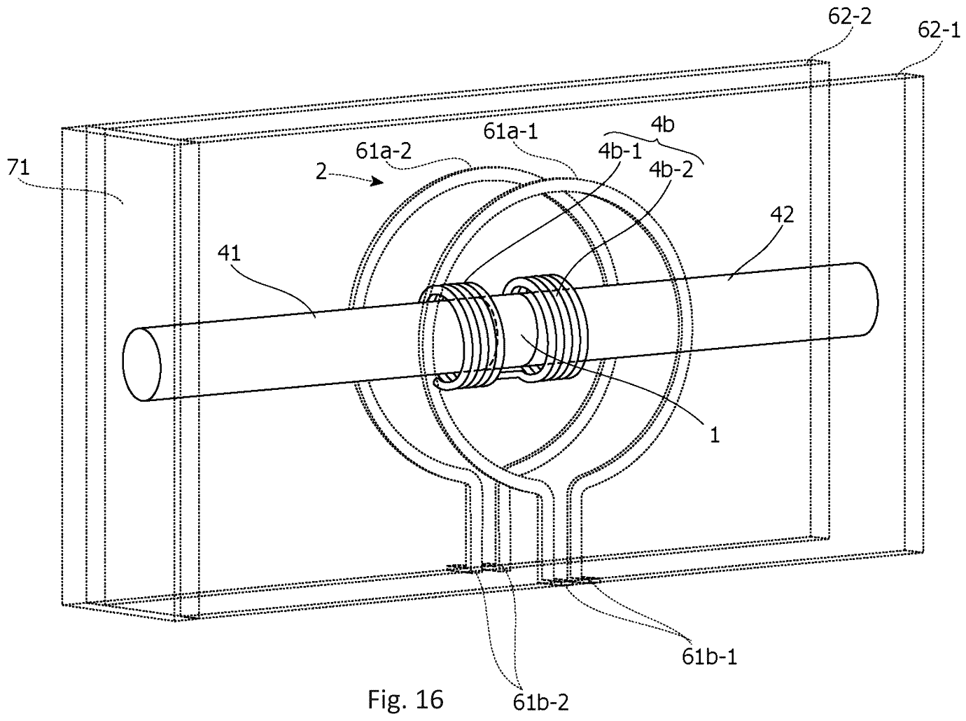

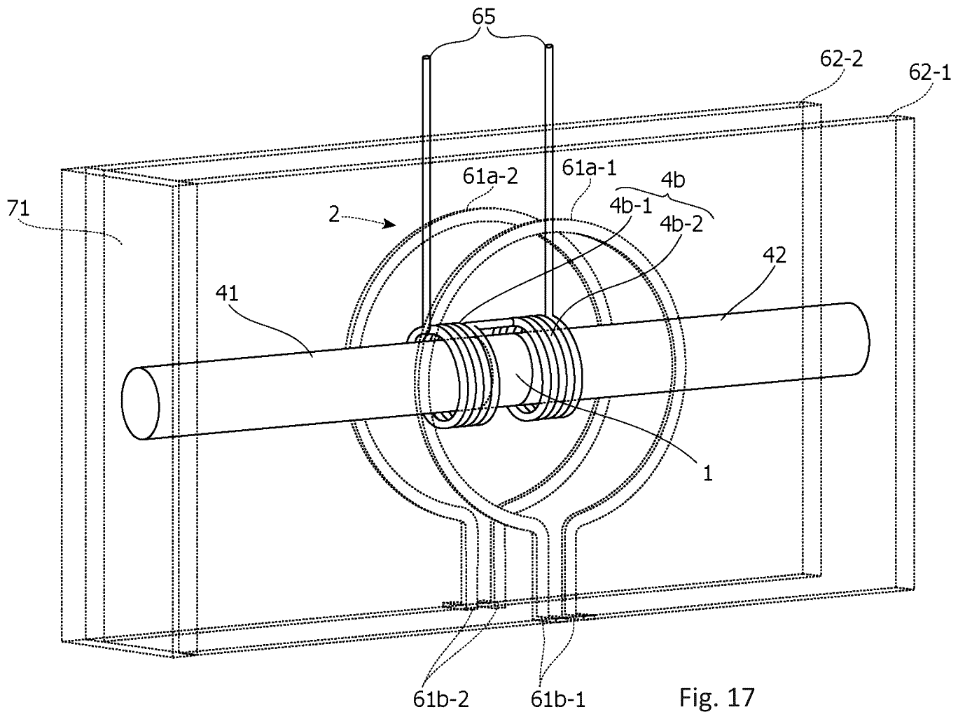

FIGS. 16 and 17 are perspective views that show examples of a secondary coil of a flux transformer 4 according to a sixth embodiment.

In the sixth embodiment, as shown in, for instance, FIGS. 16 and 17, the secondary coil 4b of the flux transformer 4 is divided into two split coils 4b-1 and 4b-2. The two split coils 4b-1 and 4b-2 are electrically connected in series or in parallel (here, in series). The split coils 4b-1 and 4b-2 of the secondary coil 4b induce an applied magnetic field corresponding to the above-mentioned electrical signal.

Further, as shown in, for instance, FIG. 17, the split coils 4b-1 and 4b-2 may be electrically connected in series. Further, ends 65 of the secondary coil 4b may extend in the opposite direction to the terminal parts 61b-1 and 61b-2 of the high frequency magnetic field generator 2.

Note that the other configurations and operations of the magnetic field measurement device according to the sixth embodiment are the same as those explained in any other embodiments. Therefore, the explanations of the other configurations and operations of the measurement device according to the sixth embodiment will be omitted.

### Seventh Embodiment

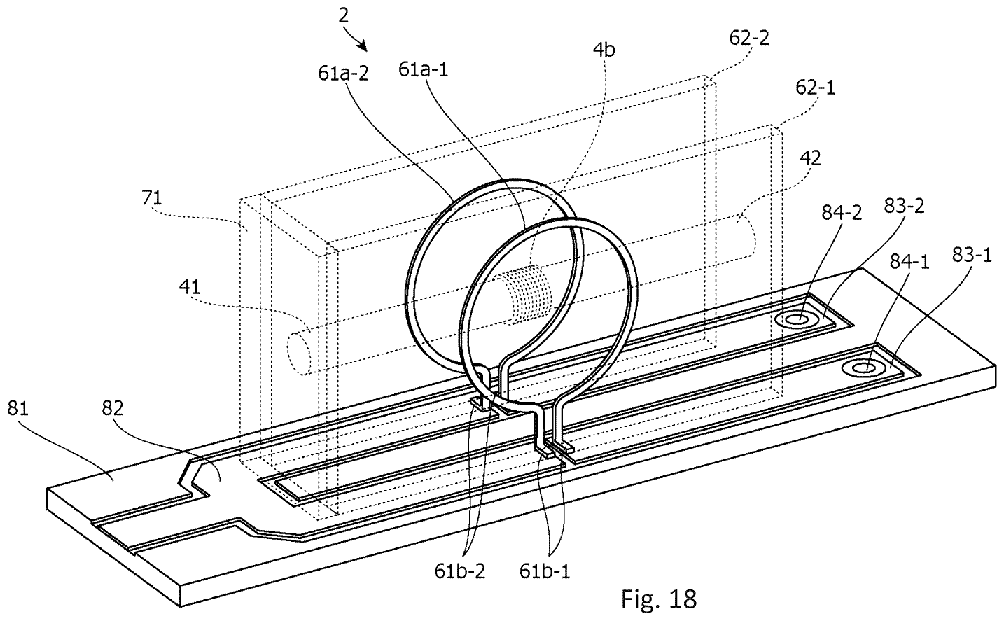

FIG. 18 is a perspective view that shows a configuration of a magnetic sensor part (a part) in a magnetic field measurement device according to a seventh embodiment. In the seventh embodiment, as shown in, for instance, FIG. 18, a substrate 81 is provided. The substrate 81 has wiring patterns 82, 83-1, and 83-2 for conducting the high frequency current of the above-mentioned microwave.

Further, on the substrate 81, the plate members 62-1 and 62-2 are respectively arranged upright and fixed to the substrate 81. The terminal parts 61b-1 and 61b-2 are electrically connected to the wiring patterns 82, 83-1, and 83-2 of the substrate 81 by such as soldering.

Specifically, one of the terminal parts 61b-1 and one of the terminal parts 61b-2 are connected to the wiring pattern 82. The other of the terminal parts 61b-1 and the other of the terminal parts 61b-2 are connected to the wiring patterns 83-1 and 83-2, respectively. Further, the wiring pattern 82 is electrically connected to the high frequency power source 11. The wiring patterns 83-1 and 83-2 are terminated, for instance, at through holes 84-1 and 84-2. Note that end portions of the wiring patterns 83-1 and 83-2 are not limited to the through holes shown in the figure.

Note that the other configurations and operations of the magnetic field measurement device according to the seventh embodiment are the same as those explained in any other embodiments. Therefore, the explanations of the other configurations and operations of the measurement device according to the seventh embodiment will be omitted.

### Eighth Embodiment

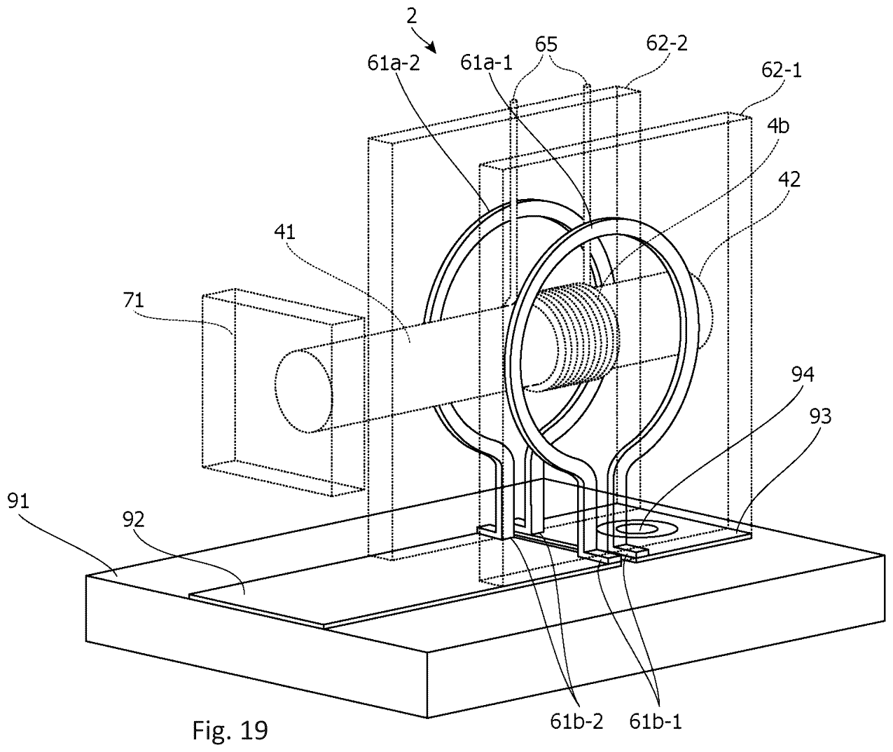

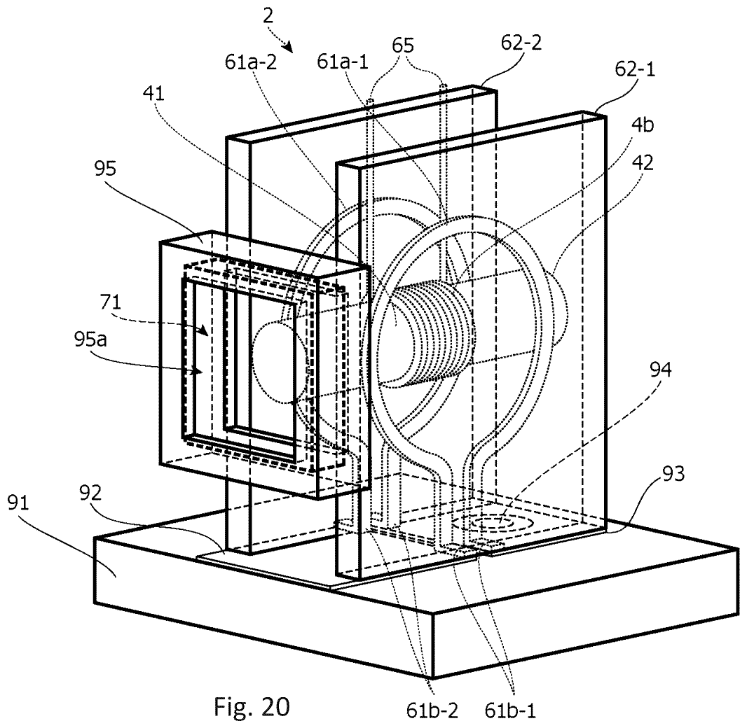

FIGS. 19 and 20 are perspective views that show configurations of a magnetic sensor part (a part) in a magnetic field measurement device according to an eighth embodiment. In the eighth embodiment, as shown in, for instance, FIG. 19, a substrate 91 is provided. The substrate 91 has wiring patterns 92 and 93 for conducting the high frequency current of the above-mentioned microwave.

Further, on the substrate 91, the plate members 62-1 and 62-2 are respectively arranged upright and fixed to the substrate 91. The terminal parts 61b-1 and 61b-2 are electrically connected to the wiring patterns 92 and 93 of the substrate 91 by such as soldering.

Specifically, one of the terminal parts 61b-1 and one of the terminal parts 61b-2 are connected to the wiring pattern 92. The other of the terminal parts 61b-1 and the other of the terminal parts 61b-2 are connected to the wiring patterns 93. Further, the wiring pattern 92 is electrically connected to the high frequency power source 11. The wiring pattern 93 is terminated at a through hole 94.

Furthermore, as shown in, for instance, FIG. 19, the ends 65 of the secondary coil 4b extend in an opposite direction with respect to the substrate 91.

FIG. 20 shows a variation of the magnetic sensor part 10 according to the eighth embodiment. As shown in, for instance, FIG. 20, the optical member 71 is fixed by a frame member 95. Further, the frame member 95 is fixed to and in contact with the side surfaces (side surfaces perpendicular to the substrate 91) of the plate members 62-1 and 62-2.

Note that the other configurations and operations of the magnetic field measurement device according to the eighth embodiment are the same as those explained in any other embodiments. Therefore, the explanations of the other configurations and operations of the measurement device according to the eighth embodiment will be omitted.

### Ninth Embodiment

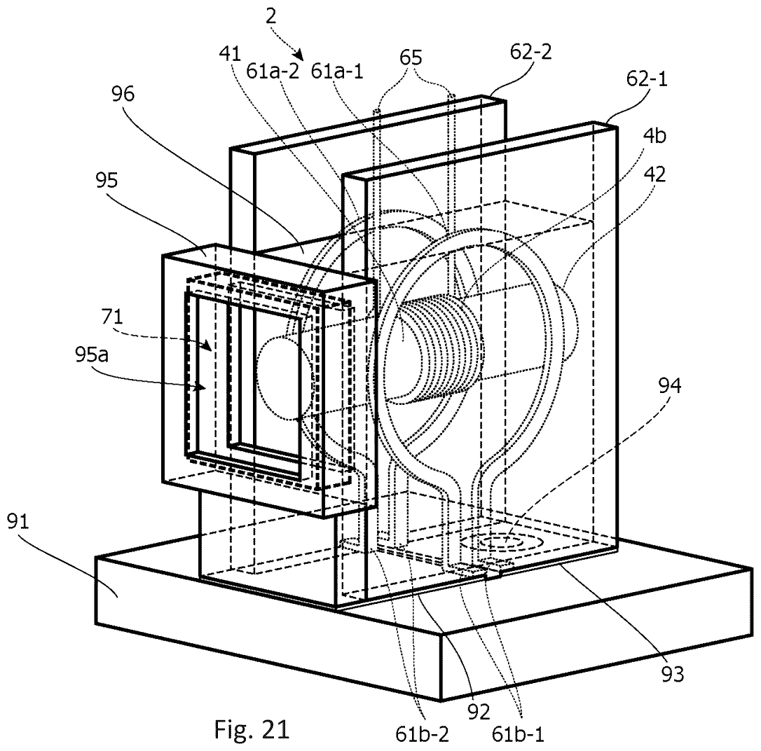

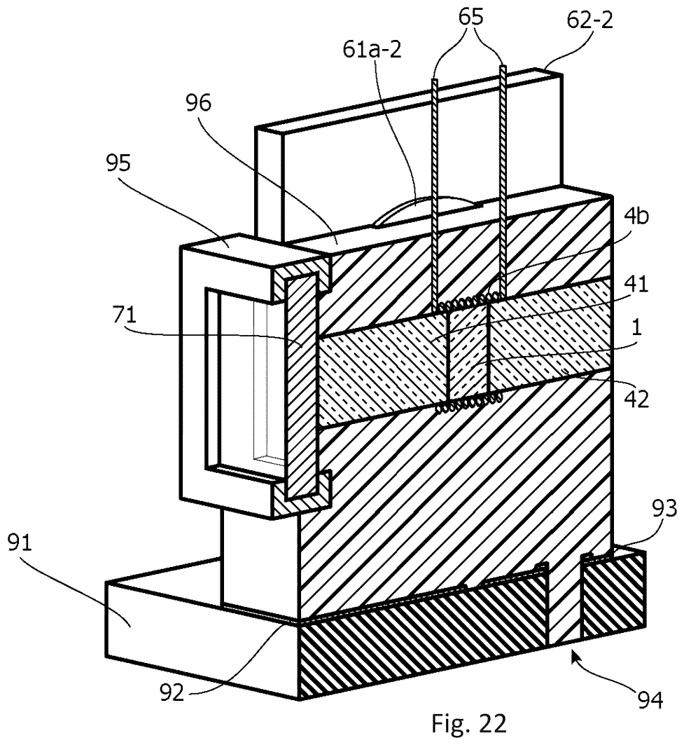

FIG. 21 is a perspective view that shows a configuration of a magnetic sensor part (a part) in a magnetic field measurement device according to a ninth embodiment. FIG. 22 is a cross-sectional view that shows the configuration of the magnetic sensor part (a part) in the magnetic field measurement device according to the ninth embodiment.

The magnetic sensor part 10 shown in FIGS. 21 and 22 is obtained by adding a filling member 96 to the above-mentioned magnetic sensor part 10 shown in FIG. 20. The filling member 96 is formed by filling the space between the plate member 62-1 and the plate member 62-2 (more specifically, the space surrounded by the plate members 62-1 and 62-2, the substrate 91, and the frame member 95) with a curable (curing) resin (such as thermosetting resin).

As shown in, for instance, FIG. 20, the light guide members 41 and 42, the magnetic resonance member 1, and the secondary coil 4b are assembled, and at the same time, the plate members 62-1 and 62-2, the substrate 91, and the frame member 95 are assembled. Thereafter, in a state in which the assembly of the light guide members 41 and 42, the magnetic resonance member 1, and the secondary coil 4b is placed in an inside of the above-mentioned space by using, for example, a jig, the curable resin is injected and cured (hardened) so as to form the filling member 96. Further, at this time, with respect to open portions at the bottom of the optical member 71 and the frame member 95 and open portions on the opposite side of the optical member 71 and the frame member 95, temporary frames are arranged as necessary to prevent the injected curable resin from leaking out and are removed after the curing.

Note that the other configurations and operations of the magnetic field measurement device according to the ninth embodiment are the same as those explained in any other embodiments. Therefore, the explanations of the other configurations and operations of the measurement device according to the ninth embodiment will be omitted.

### Tenth Embodiment

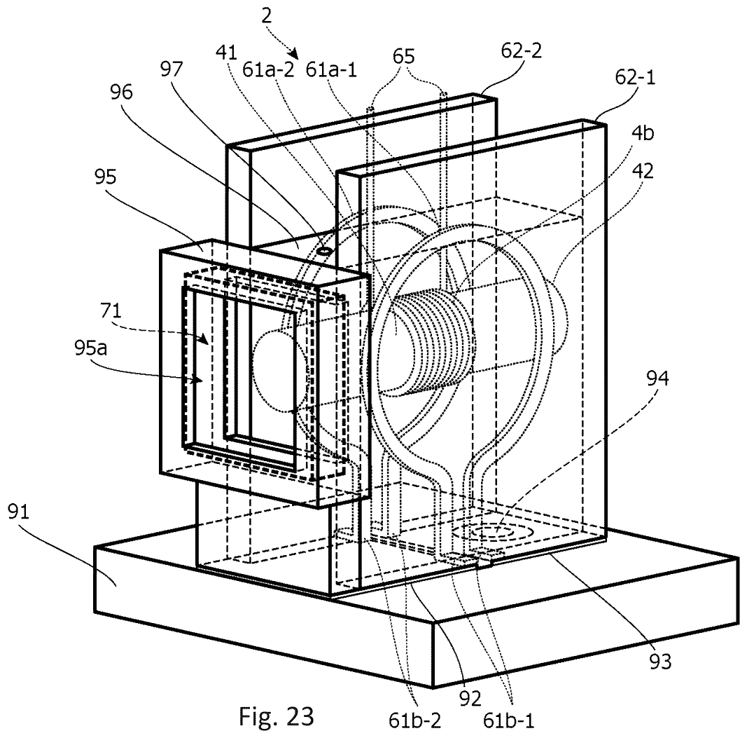

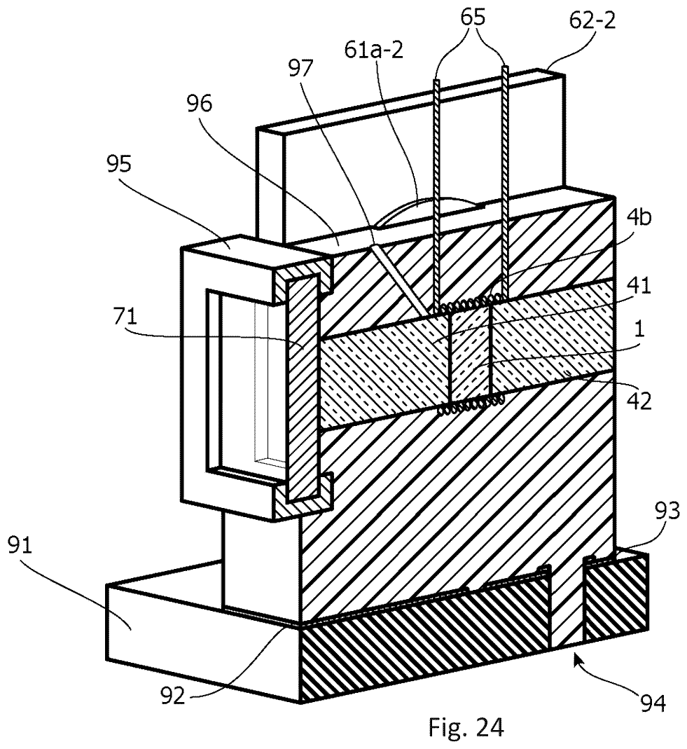

FIG. 23 is a perspective view that shows a configuration of a magnetic sensor part (a part) in a magnetic field measurement device according to a tenth embodiment. FIG. 24 is a cross-sectional view that shows the configuration of the magnetic sensor part (a part) in the magnetic field measurement device according to the tenth embodiment.

In the tenth embodiment, as shown in FIGS. 23 and 24, the filling member 96 has an observation hole 97 for optically observing the magnetic resonance member 1 from the side opposite to the substrate 91. For instance, a fiberscope is inserted into the observation hole 97 and the magnetic resonance member 1 is observed with the fiberscope. Further, when the observation is not being performed, a light shielding member is attached to the observation hole 97 so as to prevent external light from entering into the magnetic resonance member 1.

Note that the other configurations and operations of the magnetic field measurement device according to the tenth embodiment are the same as those explained in the ninth embodiment. Therefore, the explanations of the other configurations and operations of the measurement device according to the tenth embodiment will be omitted.

Note that various changes and modifications to the embodiments described above will be apparent to one having ordinally skill in the art. Such the changes and modifications may be made without departing from the spirit and scope of the subject matter and without diminishing the intended advantages. That is, it is intended that such the changes and modifications are included within the scope of the claims.

For instance, in any of the above-mentioned embodiments, the magnet 3 may be an electromagnet.

Further, in any of the above-mentioned embodiments, a reflection film (such as a dielectric multilayer film) may be provided on the side surfaces of the light guide members 41 and 42. Furthermore, a reflection film (such as a dielectric multilayer film) may be provided on the side surfaces of the CPCs 43a and 43b.

Furthermore, in any of the above-mentioned embodiments, the light guide members 41 and 42 may have the same length. In addition, the cross-sectional shapes of the light guide members 41 and 42 are not limited to a circle or a rectangle. The cross-sectional shapes may be another shape such as a hexagon. Furthermore, the material of the light guide members 41 and 42 may be a transparent resin such as an acrylic resin.

Furthermore, in any of the above-mentioned embodiments, the secondary coil 4b may be wound directly around at least one of the first light guide member 41, the second light guide member 42, and the magnetic resonance member 1.

Furthermore, in any of the above-mentioned embodiments, the secondary coil 4b may be made of a copper wire with a transparent coating. In this case, a part of the fluorescence, which is emitted from the magnetic resonance member 1 to the outside of the magnetic resonance member 1 and the light guide members 41 and 42, is reflected on the surface of the copper wire via the transparent coating and returns to the inside of the light guide members 41 and 42 or the magnetic resonance member 1. Therefore, the light amount of fluorescence received by the light receiving device 13 is increased.

Furthermore, in any of the above-mentioned embodiments, the secondary coil 4b may be a coil wound at many layers (a multilayer-wound coil).

Further, in the above-mentioned embodiments, the secondary coil is the bobbinless coil. However, the secondary coil may be wound around a bobbin as necessary. In this case, the bobbin has a through hole and supports the above-mentioned light guide members 41 and 42 (and the magnetic resonance member 1) that are inserted into the through hole.

### INDUSTRIAL APPLICABILITY

The present invention can be applicable to, for instance, a magnetic field measurement device.

1. A magnetic field measurement device comprising:
a magnetic resonance member configured to perform an electron spin quantum operation via a microwave;
a high frequency magnetic field generator configured to apply the microwave to the magnetic resonance member;
a magnet configured to apply a static magnetic field to the magnetic resonance member;
an irradiation device configured to irradiate incident light having a specific wavelength to the magnetic resonance member;
a flux transformer configured to:
sense a measured magnetic field with a primary coil; and
apply an applied magnetic field corresponding to the sensed measured magnetic field to the magnetic resonance member with a secondary coil;
a first light guide member that is in a cylindrical shape, the first light guide member being configured to guide the incident light to the magnetic resonance member; and
a second light guide member that is in a cylindrical shape, the second light guide member being configured to guide fluorescence emitted by the magnetic resonance member from the magnetic resonance member,
wherein the magnetic resonance member is arranged to be sandwiched between an end surface of the first light guide member and an end surface of the second light guide member in a hollow part of the secondary coil of the flux transformer and in a hollow part of the magnet, and
the secondary coil is a bobbinless coil.

2. The magnetic field measurement device according to claim 1,
wherein the high frequency magnetic field generator includes a coil part that is configured to emit the microwave, the coil part being in a substantially circular and plate shape, the coil part having two openings,
the first light guide member is arranged so as to pass through one of the two openings, and
the second light guide member is arranged so as to pass through the other of the two openings.

3. The magnetic field measurement device according to claim 1,
wherein the high frequency magnetic field generator includes two coil parts that are configured to emit the microwave, the two coil parts being in a substantially circular shape, and
at least a part of the first light guide member and at least a part of the second light guide member are arranged in a space between the two coil parts.

4. The magnetic field measurement device according to claim 3, further comprising:
a substrate having a wiring pattern for conducting a high frequency current of the microwave;
a first plate member; and
a second plate member arranged substantially parallel to the first plate member,
wherein a first coil part of the two coil parts is arranged on a surface of the first plate member, and a second coil part of the two coil parts is arranged on a surface of the second plate member facing the surface of the first plate member,
the high frequency magnetic field generator further includes a first terminal part extending from the first coil part along a side surface of the first plate member and a second terminal part extending from the second coil part along a side surface of the second plate member,
each of the first plate member and the second plate member is arranged upright on the substrate, and
the first terminal part and the second terminal part are electrically connected to the wiring pattern of the substrate.

5. The magnetic field measurement device according to claim 4, further comprising:
a filling member formed by filling a space between the first plate member and the second plate member with a curable resin.

6. The magnetic field measurement device according to claim 5,
wherein the filling member has an observation hole for optically observing the magnetic resonance member from a side opposite to the substrate.

7. The magnetic field measurement device according to claim 1, further comprising:
an optical member arranged adjacent to an end surface of the first light guide member, the optical member being configured to transmit the excitation light and reflect the fluorescence.

8. The magnetic field measurement device according to claim 1,
wherein the secondary coil is wound around at least one of the first light guide member, the second light guide member, and the magnetic resonance member.

9. The magnetic field measurement device according to claim 1,
wherein the secondary coil includes a copper wire and a transparent coating.
